(19) United States
(12) Patent Application Publication
(10) Pub. No.: US 2026/0227170 A1
(43) Pub. Date: Aug. 6, 2026

(54) IMPROVED MEASUREMENT PROBE FOR TESTING COATING THICKNESS ON FLAT SHEETS

(71) Applicant: Innosen Limited, Hong Kong (CN)

(72) Inventor: Lucien Nelen, Hong Kong (CN)

(73) Assignee: Innosen Limited, Hong Kong (CN)

(21) Appl. No.: 19/154,918

(22) PCT Filed: Feb. 8, 2024
(86) PCT No.: PCT/EP2024/053146

§ 371 Date: Aug. 8, 2025

(30) Foreign Application Priority Data
Feb. 10, 2023 (GB) 2301890.6

(51) Int. Cl. G01B 7/06; G01B 1/00; G01B 7/00; G01R 27/26

(52) U.S. Cl. CPC G01B 7/085; G01B 1/00; G01B 7/002; G01R 27/2605

(57) ABSTRACT

A probe (2) has a handle (4), an upper part having first and second cable connection sockets (8a, 8b) and a compressed air connector (10) and a lower weighted part (12). The base (14) of the probe is conductive, being provided with an annular ring (16) of a carbide material surrounding a large metal disc (18) that has a series of spaced apart air outlets (20). A probe tip (22) of conductive rubber surrounded by a tip holder (23) is provided within an insulated socket (24) within the base of the probe. The tip (22) of the probe (2) provides a first electrode for forming a capacitor and the metal disc (18) and ring (16) form a second electrode of the capacitor.

### FIELD OF THE INVENTION

The present invention relates generally to an improved probe for measuring thin coating, lacquer and varnish thickness of flat metal sheets, such as those used for metal containers including food and beverage containers. Generally, the probe is used in conjunction with a capacitive thickness gauge.

### BACKGROUND

The manufacture of metal cans for storing food and beverages uses tin plate or tin-free steel sheets that are formed into the containers. The container is then filled and sealed. It is important to prevent any interaction between its contents and the metal of the container and therefore the metal is typically protected with one or more coats of lacquer. The lacquer prevents direct contact between the contents of the can and the metal. This assures that the contents cannot cause corrosion of the metal container and makes sure that the metal does not adversely affect the quality of the content (taste, color etc,).

The lacquer is normally applied by a machine equipped with rollers that apply a certain lacquer layer thickness onto the metal sheet. The lacquer is applied as a very thin coating and should be uniform across the sheet. Often, the applied lacquer is uniform along the length of the sheet but variations may exist across its width. Testing is performed on the sheets to check the integrity of the lacquer. Various measurement methods exist to make sure the lacquer layer has the correct thickness across the sheet, some using wet layers and others that can only measure layers once they have been cured.

Wet film thickness can be measured in a number of ways. The solid content and the specific gravity of the lacquer is known, so it is possible to determine the lacquer layer thickness by weighing. To this end a metal sheet is weighed before and after it has been coated. The weight difference is the total wet lacquer weight on the sheet. Using the solids ratio of the lacquer this can be used to calculate the dry film-weight. Using the specific gravity of the lacquer that can be used to calculate the lacquer layer thickness.

This method suffers from repeatability problems because the solvent in the lacquer evaporates on the way to the weighing scale. The longer the transit takes, the more lacquer will have evaporated resulting in the film-weight seeming less. Furthermore, this method provides no information about the distribution of the film thickness over the sheet.

An alternative wet layer method uses a lacquer comb consisting of a rectangular piece of metal that has indents of various depth on one side. By pushing the “comb” onto the metal and dragging it across the surface the deeper indents will not touch the lacquer surface. The shallowest indent that touches determines the thickness. Near infrared absorption methods may also be employed to measure the coating thickness which use specific wavelengths in the near infrared wavelength band at which the lacquer absorbs and other wavelengths where the lacquer does not absorb, thereby enabling one to calculate the thickness of the lacquer layer. White light interferometry methods may also be used to calculate the thickness of the lacquer layer as well as beta back scattering. This system uses a beta ray source that radiates the sheet. The lacquer absorbs the β radiation and the metal substrate reflects the radiation back. Each lacquer has its own absorption coefficient, so the extinction can be used to calculate the layer thickness/layer-weight.

A number of systems exist for dry weight measurement. The systems described above for wet film-weight using NIR, white light interferometry and β-backscattering also work for dry lacquers. Additionally, ultrasonic or capacitive methods may be used. The former uses time of flight for an ultrasonic pulse to calculate the thickness of the lacquer layer. This method does not work well for very thin layers as the time between the original emitted pulse and the reflection is so short that accurate measurements are impossible. Capacitive methods are more commonly used for thin lacquer layers, using equipment provided by companies such as StrandGauge™ from Strand Electronics Ltd and a hoverprobe sold by companies such as Innosen in conjunction with a capacitive thickness gauge of Sencon.

The gauge known as StrandGauge™ consists of an electronics unit and a probe. The probe is a plexiglass disk that has a spring loaded attachment. At the end of the spring-loaded attachment is a piece of conductive rubber that is pushed against the lacquer film. This forms a first electrode of the capacitor and an alligator clip is also provided for connection to the metal substrate to form the second electrode, with the lacquer acting as a dielectric between the electrodes.

The capacitance is given by the formula:

$$C = ( ε \times A ) / d$$

where ε is the dielectric constant of the lacquer, A is the probe surface area (that is, the surface area of the conductive rubber tip of the probe), and d is the distance between the plates (i.e. the lacquer thickness). By using the gauge as a comparator to a known calibration standard sample, both ε and A become constant so variation in capacitance is due to the difference in d, thus enabling measurement of the thickness of the layer. The constants are stored in the gauge for future use.

For the measurement to be accurate the surface area of the conductive rubber tip needs to remain the same. The conductive rubber tip also needs to conform to the lacquered surface in order to get a good capacitance reading (i.e., no air should be trapped between the lacquer layer and the conductive rubber tip). However, the use of a spring to provide a compression force on the conductive rubber tip was found to be too variable. The spring can expand and contract with temperature and also pushing down the probe against the spring pressure results in this process not being an accurately repeatable process.

The Inventor previously created the hoverprobe to address these issues. This type of probe uses a dead weight instead of a spring. The weight pushes down directly on the conductive rubber tip and was found to provide more consistent readings. The deadweight is quite heavy so the probe is provided as an air bearing. The probe has a compressed air connection and at the push of a button the compressed air raises the weight so that the whole probe is able to hover over the sheet on an air bearing. Once the button is released, the probe's weight settles on the sheet, allowing the probe tip to measure the coating thickness rapidly and accurately.

This type of system has proven very popular in the industry but a number of problems may still arise which would be desirable to address. For example, the use of an alligator clip for connection to the metal substrate for forming the second electrode scratches the coating applied to the surface of the substrate. Additionally, stray capacitance variations is a significant problem due to the need to use lengthy cables between the probe and gauge which can affect the accuracy of the result obtained. Frequent re-calibrations of the system are recommended to minimize this issue but are not always carried out correctly, if at all. This reduces the reliability of the output of the system.

It is an object of the present invention to provide an improved measurement probe, in particular an air cushion measurement probe, that overcomes, or at least alleviates, the abovementioned problems.

### SUMMARY OF THE INVENTION.

According to a first aspect of the present invention there is provided a probe for measuring capacitance of a thin coating, lacquer or varnish applied to a metal sheet, the probe comprising a main body part including at least one weight and a base including at least one conductive probe tip, wherein at least part of the base that contacts the metal sheet is made from a conductive material.

The weight provided in the main body part is of a sufficient size to provide a compression force to the probe tip that ensures that the tip conforms to the coated/lacquered surface of the sheet, overcoming any surface roughness of the coating which leads to inaccurate measurements using the probe. The actual size of the weight provided depends upon the surface area of the tip, with smaller tips requiring less weight but conventionally the dead weight may be 3-4 kg with the whole probe being 5-8 kg. However, it is to be appreciated that the probe of the present invention is not limited to a weight of any particular size.

The conductive material of the base preferably comprises a conductive plate, preferably being a metallic plate such as a plate of stainless steel. However, it is to be appreciated that any material may be used provided that the part of the base that contacts the metal sheet is conductive, such as a plastic plate coated in a hard chrome. The conductive material should have a hardness greater than tinplate and provide a smooth, flat conductive surface. Thus, preferably the conductive material has a hardness greater than 79 HRC.

The edges of the metallic base are preferably surrounded by an extremely hard, conductive material, such as carbide. This has a hardness of at least 84 HRC. Alternative materials may be used around the perimeter of the base, such as hard chrome. The base may be formed entirely of this material but, due to cost, it is preferable to provide a metallic base plate surrounded by an outer perimeter of this harder material. This serves to protect the base plate from scratches caused by movement of the probe on the sheet of tinplate which, in turn, would scratch and damage the lacquer coating.

Preferably, the base is circular with an annular ring of harder conductive material around its perimeter. Preferably, the probe tip is provided in the centre of the base. Preferably, the probe tip comprises conductive rubber. The probe tip is preferably removable from the base. More preferably, the probe tip is provided within a holder for receipt within a recess or socket in the base of the probe. The holder preferably includes gripping means to aid insertion and removal of the tip from the base. Preferably, the holder includes at least one hole. The probe tip and holder preferably form a cylindrical T-shaped member, having a head and shank. The holder and probe tip preferably form a banana-like plug. However, other types of holder may be provided but preferably, the arrangement allows easy extraction and insertion of the probe tip within the recess/socket. For example, the holder may have an outer threaded region for mating with a threaded region in the socket. The holder should be a conductive material, for example, a gold-plated brass holder.

In a preferred embodiment, a side of the holder includes at least one groove or recess for allowing gripping of the holder by an extraction tool for easy extraction and insertion and/or includes at least one hole for release of air. More preferably, the head of the T-shaped member is provided with a groove extending around its circumference. Preferably, a side of the head is provided with the at least one hole.

An insulating material is provided between the probe tip and the conductive base, for example in the recess/socket for receipt of the probe tip. Preferably, the insulating material is Teflon. However, other insulating materials may be provided between the probe tip and conductive base, such as high density polyethylene (HDPE) or acetal.

The probe is preferably provided with a handle, preferably extending from an upper surface of the main body of the probe. Appropriate electrical connection sockets are provided on the probe, for example for connection to a capacitive thickness gauge.

Preferably, the capacitance probe is connectable to an air supply, the probe having air passages to outlets in the base of the probe. Preferably the air outlets extend through the conductive base plate at spaced apart intervals. An actuator is preferably provided on the probe to open the air outlets to deliver air to the base of the probe. Preferably, the actuator comprises a button, preferably being provided on the handle of the probe.

A second aspect of the present invention provides a coating thickness gauge comprising a probe according to the first aspect of the present invention and an electronic measurement device connected to or provided within the probe, optionally wherein the measurement device displays at least one parameter relating to the coating thickness.

Preferably, a removable connector cable is provided for connecting the thickness gauge to the measurement device. Optionally, an additional removable connector cable with crocodile clip may be provided to connect the probe to a metal sheet.

In a preferred embodiment of the present invention, the conductive base of the probe serves as the second electrode and the electronics to measure the capacitance are incorporated directly into the probe. This enables less cabling and cheaper, standard cabling to be connected to the probe. In this respect, current cabling for the satisfactory transmission of signals from the probe/crocodile clip to a capacitance gauge for measurement within the gauge are sophisticated and expensive. The ability to provide the measurements within the probe itself and then transmit the measured data to a remote receiver, such as a gauge, enables cheap, standard cabling to be used. The measurement of the capacitance within the probe also eliminates the effect of the cabling capacitance on the reading obtained. The probe may include a display and/or the measurements may be communicated to a remote receiver such as gauge or computer, for example via wireless communication, Bluetooth or a USB cable. Preferably, a USB cable is provided to transfer data and provide power to the probe but power could also be provided by batteries, preferably rechargeable batteries, provided inside the probe.

A third aspect of the present invention provides a method of measuring the thickness of coating, lacquer or varnish on a flat, metal sheet comprising:
activating an air supply to the base of a probe according to the first aspect of the present invention;
moving the probe across a metal sheet to a location for a thickness measurement;
deactivating the air supply to the base of the probe to settle the probe on the sheet;
forming capacitance in series between the metal sheet and the probe tip and between the metal sheet and the base of the probe or another electrode; and
providing a reading of the capacitance to measure the thickness of the coating, lacquer or varnish on the metal sheet.

Thus, the method does not require connection of a crocodile clip to the metal sheet due to the base of the probe serving as the second electrode. However, connection of a crocodile clip may be provided as an optional step wherein the base of the probe no longer serves as the other electrode.

Preferably, measuring the capacitance to provide the thickness of the coating, lacquer or varnish on the metal sheet is carried out within the probe. Alternatively, the method may further comprise connecting the probe to a thickness gauge.

A fourth aspect of the present invention provides a probe tip comprising a conductive tip partially encased in a holder of a non-corrosive, conductive material.

Preferably, the probe tip is made from a conductive rubber material and is encased in a gold-plated brass holder. More preferably, the probe tip with holder forms a banana-like plug. In a preferred embodiment, a side of the holder includes at least one groove, hole or recess for allowing gripping of the holder by an extraction tool for easy extraction and insertion. Preferably, the side of the holder includes a groove or recess and at least one air release hole.

The probe tip and holder preferably form a cylindrical T-shaped member, having a head and shank. More preferably, the head of the T-shaped member is provided with a groove extending around its circumference. Optionally, the head is also provided with at least one air release hole.

Alternatively, the holder may have an outer threaded region.

Multiple probe tips may be provided within a housing, preferably being provided with an extraction tool for their removal from the probe and/or housing and insertion into the base of the probe.

### BRIEF DESCRIPTION OF THE DRAWINGS

For a better understanding of the present invention and to show more clearly how it may be carried into effect, reference will now be made by way of example only to the accompanying drawings in which:

FIG. 1 is a front view of a measurement probe according to an embodiment of one embodiment of the present invention, shown with probe tip removed;

FIG. 2 is an isometric bottom view of the probe of FIG. 1, shown with the probe tip removed;

FIG. 3 illustrates the probe of FIGS. 1 and 2 resting on a metal sheet;

FIG. 4A illustrates one embodiment of a connector cable for connection of the measurement probe shown in FIGS. 1 to 3 to a thickness gauge;

FIG. 4B illustrates the connector cable of FIG. 4A connected to the probe shown in FIG. 3;

FIG. 5A illustrates another embodiment of a connector cable with a crocodile clip for connection of the measurement probe shown in FIGS. 1 to 3 to a thickness gauge and metal sheet;

FIG. 5B illustrates the connector cable with crocodile clip of FIG. 5A connected to the probe shown in FIG. 3 and a metal sheet;

FIGS. 6A to 6B illustrate extraction of a probe tip from the probe;

FIG. 6C is an expanded view of a probe tip according to an embodiment of the present invention; and

FIG. 6D illustrates a probe tip housing containing multiple probe tips and an extraction tool.

### DETAILED DESCRIPTION

The present invention provides an improved probe for measuring thin coating, lacquer and varnish thickness of flat metal sheets, such as those used for metal containers including food and beverage cans. Conventionally, the probe is used in conjunction with a thickness gauge, being connected thereto by suitable, specialist cables. The probe is brought into contact with a component surface to provide data relating to the thickness of the coating on the component surface. The probe according to the present invention is designed to minimize operator variance that is normally experienced when measuring lacquer thickness and reduces the variance of stray capacitance created via the cabling thereby providing a more accurate and repeatable reading of the thickness of the coating, lacquer or varnish. In embodiments, the probe also provides both electrodes thereby removing the requirement for attachment of a crocodile clip to the metal sheet to form one of the electrodes which can damage the metal sheet.

The probe is an improvement to an existing probe known as a “hoverprobe” sold by the Applicant under Product No. IS9650 which uses an air cushion to glide a dead weight carrying a probe tip into place on the surface of a metal sheet. In the prior art, the main body of the probe forms the dead weight and air is supplied through ducts to air outlets in the base of the probe, thereby allowing the probe to float across the surface of a metal sheet. This existing probe has a probe tip comprising a piece of conductive rubber that is placed within a tip socket provided in the base of the probe, the socket surrounded by a much larger disc of plastics material that includes the air outlets. A first cable extends internally within the device to the probe tip and a second cable is provided with a crocodile clip for connection to the metal sheet. In this manner, the probe tip forms the first electrode and the metal sheet forms the second electrode to enable the capacitance to be measured for calculation of the lacquer thickness.

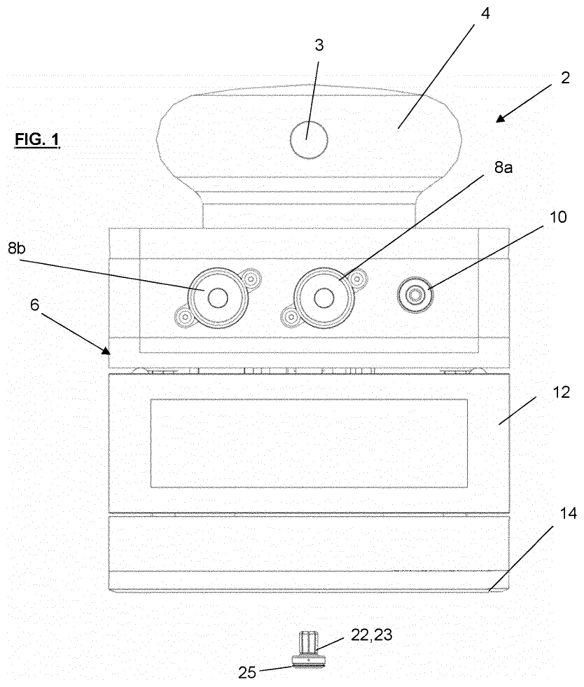

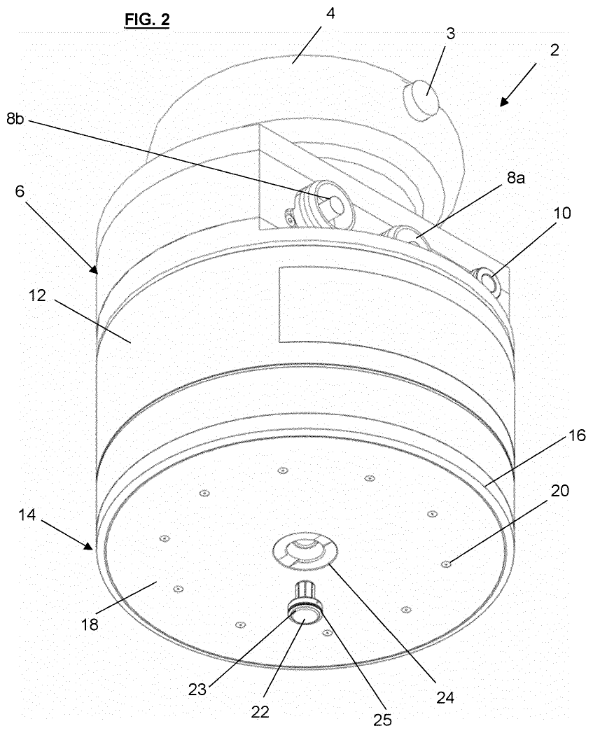

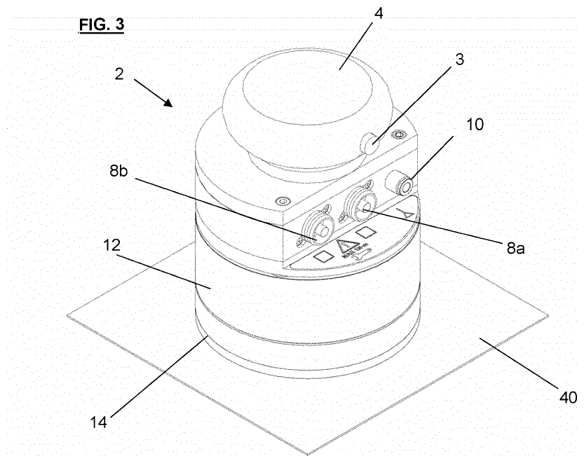

It is desirable to provide an improved probe that reduces the amount and complexity of the cabling that forms part of the measurement circuit and furthermore, can remove the need for attachment of a crocodile clip to the metal sheet. The present invention achieves this by providing both electrodes within the base of the probe. FIGS. 1 to 3 of the accompanying drawings illustrate one embodiment of a probe 2 according to the present invention. The probe 2 comprises a handle 4 with a button 3, the handle extending upwardly from a cylindrical housing 6 that includes an upper part having first and second cable connection sockets 8a, 8b and a compressed air connector 10 and a lower weighted ring 12. The base 14 of the probe is provided with an annular ring 16 of a hard, conductive carbide material surrounding a large metal disc 18, for example of stainless steel, that has a series of spaced apart air outlets 20 (see FIG. 2). The base is around 10 cm in diameter. A probe tip 22 of conductive rubber surrounded by a tip holder 23, for example of gold-plated brass or other non-corrosive, conductive material, is provided within a socket 24 within the base of the probe. The socket 24 comprises an annular recess of insulating material, such as Teflon, to prevent any contact between the conductive base and probe tip. Teflon is the preferred insulating material but others may be used, such as polyethylene terephthalate (PET) or acetal.

The probe 2 is able to hover over a metal sheet 40 by delivering air through the air outlets 20. In this respect, an air supply is connected to the air connector 10. Pressing button 3 on the handle activates the air supply to the air outlets 20 causing the whole probe to lift so it can float on top of the sheet. The whole unit 2 then glides over the sheet 40 on an air cushion, preventing damage to the sheet. Once at a required position above the sheet, the button 3 is released to deactivate the air supply, causing the weighted probe to settle on the sheet 40. Suitable cabling is connected to the probe 2 and a thickness gauge TG (not shown) allows measuring of the capacitance and the thickness of the coating on the metal sheet, as explained in further detail below. The air bearing principle used by the present invention also results in the probe being self-cleaning as it removes most of the dust from the surface before measuring.

The tip 22 of the probe 2 according to the present invention provides a first electrode for forming a capacitor and the annular carbide ring 16 and metal disc 18 forming the main surface area of the base 14 provide a second electrode of the capacitor. By having the conductive rubber tip 22 as one electrode of the capacitor and a much bigger piece of conductive material 16, 18 also touching the lacquer as the second electrode, two capacitors in series are provided. The second capacitor is much bigger than the first one so the effect of the second capacitor on the final reading is minimal.

The metal electrode 16, 18 should be made of a material that has a hardness greater than tinplate to prevent it from scratching. In this respect, any suitable hard metal may be used that provides a smooth, flat conductive surface, such as stainless steel. This is surrounded by a ring of much harder and more wear resistant material, such as a ring made of carbide, to prevent damage that can occur if the probe touched the edge of the metal sheets that need to be measured. This is another significant improvement over the prior art device as the carbide ring can survive impacts whereas the plastic or polymer base of the earlier probe was prone to damage.

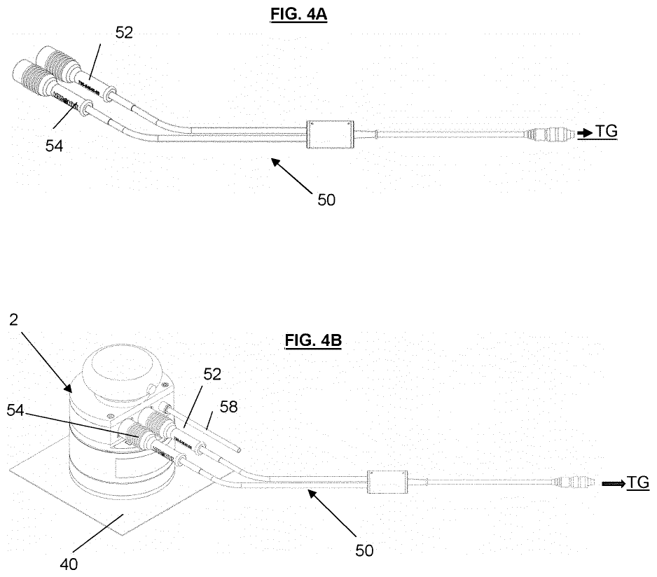

The probe according to the present invention may be used in different modes depending upon whether the metal sheet is an entirely flat surface. In a preferred “non-contact” mode suitable for use with a perfectly flat, lacquered and steady (vibration-free) metal sheet, the metal base of the probe forms the second electrode and no external cable with alligator clip has to be attached to the metal sheet. This is illustrated in FIGS. 4A and 4B of the accompanying drawings. A connector cable 50 having a first connector end 52 is connected to the first connection socket 8a of the probe and extends to a thickness gauge TG. A second connector end 54 is connected to the second connection socket 8b of the probe. In this manner, both the probe tip 22 and the base 16,18 are connected to a cable respectively. Air is supplied to the probe by connecting an air supply from an air compressor via line 58. Because no external wire is now needed to make contact with the metal substrate, the alligator clip which can damage the sheets is no longer required so sheet damage is prevented. This arrangement allows for faster measurements, with no scratches or other damage occurring to the metal sheet, thereby reducing scrap. The cables will also have a longer life span due to less wear and there is less risk of cutting the cables on the metal sheets.

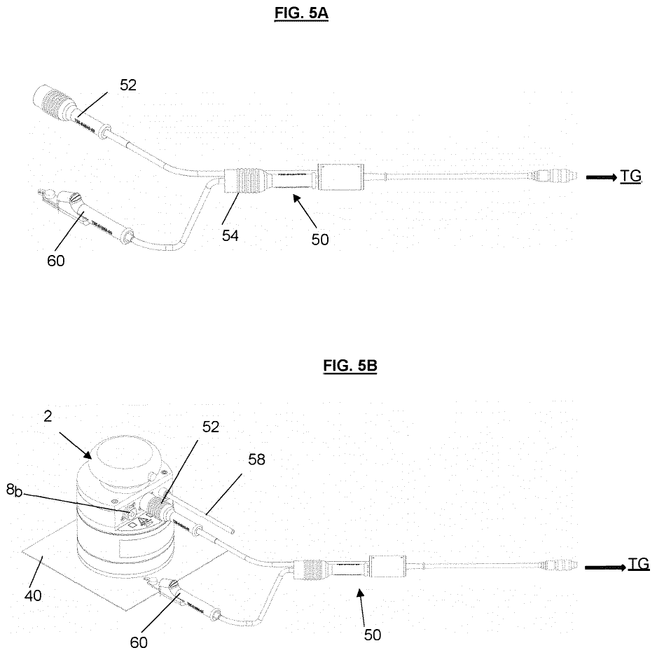

However, the probe 2 may still be operated in the conventional manner using a crocodile clip 60 attached to the metal sheet 40, as illustrated in FIGS. 5A and 5B of the accompanying drawings. The second connector end 54 is provided with a crocodile clip 60 which is attached to the metal sheet 40 rather than the second connection socket 8b of the probe 2. This “contact” mode of operation is particularly suitable for use with a non-flat metal sheet where there would be an inadequate contact level between the metal base of the probe and the sheet. It also provides the user with the option of using the probe in a conventional manner with which they are more familiar. In a further improvement of the invention the electronics to measure the capacitance are incorporated directly into the probe. This has the advantage that the cables linking the probe with the electronics unit are no longer part of the measurement circuit and as a result the cable capacitance no longer has an effect on the measured results, providing for more accurate measurements. In this respect, the inclusion of cables in the circuit is problematic as their capacitance changes with temperature and bend radius which causes poor repeatability of measurement results, particularly when long cables have to be used which is often the case due to there normally being a distance of 1-2 m between the probe and the thickness gauge that includes the electronics to measure the capacitance. Different cables also provide different results. As such, it is always necessary to calibrate out the capacitance of the cables in order to obtain a correct reading. However, operators may take measurements without such calibration which will lead to a wrong result. The incorporation of both electrodes into the probe itself enables the electronics to be incorporated into the probe itself. The values can be measured inside the probe and communicated to the outside world using standard communication protocols. Even wireless communication is possible. Thus, short or no cabling is required, reducing or even removing the need to carry out frequent calibrations of the system.

In a preferred embodiment, the measurements are recorded within the probe itself and then transmitted to a remote receiver, such as a gauge or computer, for example via wireless communication, Bluetooth or a USB cable. Preferably, a USB cable is provided to transfer data and also provide power to the probe. This provides a significant advantage over the prior art probe as it not only enables less cabling to be used but also requires cheaper, standard cabling to be connected to the probe. In this respect, current cabling for the satisfactory transmission of signals from the probe/crocodile clip to a capacitance gauge for measurement within the gauge are sophisticated and expensive. The ability to provide measurements electronically within the probe itself enables standard cabling (or even no cabling) to be used to transmit the measured data to a receiver. The measurement of the capacitance within the probe also eliminates the effect of the cabling capacitance on the reading obtained.

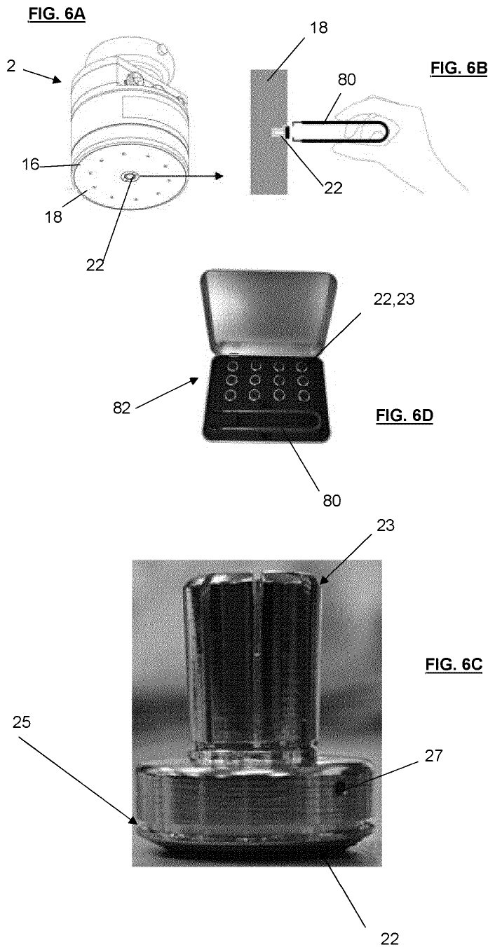

The probe 2 of the present invention may also be provided with sets of replacement probe tips 22, as demonstrated in FIGS. 6A to 6D of the accompanying drawings. Each probe tip 22 is surrounded by a gold-plated brass holder 23 in the form of a banana plug, enabling easy replacement of the tip in case of wear and tear. In the preferred illustrated embodiment, each tip and holder is a cylindrical T-shaped member having a head and shank for insertion in the socket 24 of the probe base. A groove 25 is provided around the head of the holder 23 which allows convenient gripping of the holder by an extraction tool 80. However, the holder may be provided with alternative gripping means, such as opposing recesses or holes. Additionally, the holder 23 includes at least one small hole 27 (see FIG. 6C) which, in the illustrated embodiment, is provided in a side of the head.

Multiple replacement probe tips 22 in holders 23 are provided in a housing 82 which also contains a tip extraction tool 80. Previous probe tips were not provided with an integral conductive holder 23 with groove 25 which made it very difficult to remove and insert the tips from/to the probe base socket without damage to the socket and the tip. Additionally, earlier probes trapped air when inserting a tip into the probe holder, which would reduce the accuracy of the readings obtained. The removal of this trapped air was a slow process and/or risked damaging the socket and tip during the process. In this respect, the probe would have to be left on a flat surface for at least 45 min or a small screwdriver or other suitable implement would have to be pushed along the edge to the rear of the tip. The hole 27 at the side of the holder of the improved tip allows for the release of the trapped air. Thus, the extraction tool 80 and holder 23 provided with the present invention enables easy removal and replacement without damage to the tip or base of the probe. The provision of means to grip the holder of the probe tip allows for easier and better placement and removal of the probe tip from the socket without damage. Furthermore, the hole for the release of air has heavily reduced the “settle” time as well as reducing the risk of customers damaging the tip when releasing the air. This is of benefit because the probe tip is an essential component of the measurement system and must always be in good condition for precise and repeatable measurements.

The probe according to the present invention preferably has no sealing surfaces that could cause a varying friction as the probe settles on the metal substrate/sheet. Instead, very tight tolerances around the probe cause the weight to lift up and once it is in the desired position it seals the way to prevent the escape of compressed air. In doing that the pressure inside the probe increases and the probe starts to hover. It is preferably that the probe tip is held in position by a slide bearing made out of Teflon which prevents tipping of the probe tip. Teflon has a very low coefficient of friction so supports the tip as it balances on the substrate without taking away any of the weight from the tip. Because there is no normal force on the bearing surfaces and because of the very low friction coefficient, the stiction is non-existent. Stiction is a tendency to stick-slip due to high static friction. The presence of stiction on the probe tip would affect the contact of the tip with the metal substrate/sheet.

The present invention provides an improved probe that operates on an air bearing principle that requires less cabling, reduced calibration and suffers from less wear and tear, both in relation to the parts of the probe itself and the metal sheet being measured.

Further modifications to the probe may be made without departing from the principles embodied in the examples described and illustrated herein.

1. A probe for measuring capacitance of a thin coating, lacquer or varnish applied to a metal sheet, the probe comprising a main body part including at least one weight and a base including a first and a second electrode, the first electrode comprising at least one probe tip of conductive rubber, and the second electrode comprising a metallic plate surrounded by a conductive material with a hardness greater than that of the metallic plate, and wherein an insulating material is provided between the probe tip and the metallic plate.

2. (canceled)

3. The probe as claimed in claim 1, wherein the base is circular, the probe tip is provided in the centre of the metallic plate.

4. The probe as claimed in claim 1 wherein the conductive base having a hardness of at least 80 HRC is of carbide.

5. (canceled)

6. The probe as claimed in claim 1, wherein the insulating material is Teflon.

7. (canceled)

8. The probe as claimed in claim 1, wherein the probe tip is removable from the base, the tip being provided within a holder of conductive material for receipt within a recess of the base of the probe.

9. The probe as claimed in claim 8, wherein the holder and probe tip form a banana-like plug.

10. The probe as claimed in claim 8, wherein a part of the holder includes at least one groove or recess for allowing gripping of the holder by an extraction tool for easy extraction and insertion, optionally wherein a part of the holder includes at least one hole.

11. The probe as claimed in claim 8, wherein the tip and holder form a cylindrical T-shaped member comprising a head and shank, the head being provided with a groove extending around its circumference and/or a hole in a side of the head.

12. The probe as claimed in claim 1, wherein a weight is provided in a lower part of the body part and the probe is provided with a handle extending from an upper surface of the probe.

13. The probe as claimed in claim 1 wherein the probe is connectable to an air supply, the probe having air outlets in the base of the probe, wherein the air outlets extend through the conductive base at spaced apart intervals and the actuator is provided on the probe to open the air outlets to deliver air to the base of the probe.

14. (canceled)

15. A coating thickness gauge comprising a probe according to claim 1 and an electronic measurement device connected to or provided within the probe.

16. The coating thickness gauge as claimed in claim 15, wherein a removable connector cable is provided for connecting the thickness gauge to the measurement device.

17. (canceled)

18. The coating thickness gauge as claimed in claim 15, wherein the electronics to measure the capacitance are incorporated directly into the probe.

19. The coating thickness gauge as claimed in claim 15, wherein the electronics to measure the capacitance are incorporated directly into the probe and the probe measurements are communicated to a remote receiver, for example via wireless communication or a USB cable.

20. A method of measuring the thickness of coating, lacquer or varnish on a flat, metal sheet comprising:
activating an air supply to the base of a probe according to claim 1;
moving the probe across the metal sheet to a location for a thickness measurement;
deactivating the air supply to the base of the probe to settle the probe on the sheet;
forming capacitance in series between the metal sheet and the probe tip and between the metal sheet and the base of the probe; and
providing a reading of the capacitance to measure the thickness of the coating, lacquer or varnish on the metal sheet.

21. The method according to claim 20, wherein measuring the capacitance to provide the thickness of the coating, lacquer or varnish on the metal sheet is carried out within the probe.

22. The method according to claim 2, further comprising connecting the probe to a thickness gauge, preferably via a USB cable.

23. A probe tip comprising a conductive rubber tip encased in a non-corrosive, conductive holder, wherein the holder has at least one groove, hole or recess for extraction of the probe tip using an extraction tool.

24. The probe tip as claimed in claim 23, wherein the probe tip forms a banana-like plug.

25. The probe tip as claimed in claim 23, wherein the holder includes at least one groove and at least one air release hole.
